(19) United States
(12) Patent Application Publication
(10) Pub. No.: US 2012/0052682 A1
(43) Pub. Date: Mar. 1, 2012

(54) POLISHING SLURRY AND METHOD OF MANUFACTURING SEMICONDUCTOR DEVICE USING THE SAME

(75) Inventors: Sang-Kyun Kim, Yongin-si (KR); Jong-Won Lee, Seongnam-si (KR); Eui-Hoon Jung, Suwon-si (KR); Bo-Un Yoon, Seoul (KR); Sang-Hyun Park, Hwaseong-si (KR); Seung-Jae Lee, Seoul (KR); Yun-Jeong Kim, Suwon-si (KR)

(73) Assignee: SAMSUNG ELECTRONICS CO., LTD., Suwon-si (KR)

(21) Appl. No.: 13/204,862

(22) Filed: Aug. 8, 2011

(30) Foreign Application Priority Data
Aug. 25, 2010 (KR) 10-2010-0082541

(51) Int. Cl. H01L 21/302; C09K 13/00

(52) U.S. Cl. 438/689; 252/79.1; 257/E21.214

(57) ABSTRACT

A polishing slurry for polishing an aluminum film includes an abrasive agent, an oxidizing agent, an anti-corrosion agent, and a removal rate reducing agent that is an anionic compound exhibiting a negative charge in the slurry. The polishing slurry can be used in a method of manufacturing a semiconductor device.

### CROSS-REFERENCE TO RELATED APPLICATION

This application claims priority from Korean Patent Application No. 10-2010-0082541 filed on Aug. 25, 2010, in the Korean Intellectual Property Office, and all the benefits accruing therefrom under 35 U.S.C. 119, the contents of which in its entirety are herein incorporated by reference.

### BACKGROUND OF THE INVENTION

1. Field of the Invention

The present invention relates to a polishing slurry and a method of manufacturing a semiconductor device using the same, and more particularly to a polishing slurry for polishing an aluminum film and a method of manufacturing a semiconductor device using the same.

2. Description of the Related Art

Recently, as the design rule of the semiconductor devices becomes smaller with the trend of high-integration semiconductor devices, metal patterning using a mask and an etching process has reached a limit. Accordingly, there has been proposed a damascene process capable of forming a desired metal pattern including, for example, vias, contacts and/or wiring by etching an insulating film to form trenches, and then filling the trenches with a metal material.

The damascene process utilizes a chemical mechanical polishing process in order to isolate portions of metal patterns from each other. Generally, the chemical mechanical polishing process is performed by combining a chemical action of a slurry including a chemical solution and polishing particles and a mechanical action of a polishing machine. Specifically, the mechanical removal action is performed by the polishing particles in the slurry and protrusions of the surface of a pad of the polishing machine; and the chemical removal action is performed by chemical components of the slurry.

Meanwhile, various metal materials—particularly, aluminum (Al)—may be used as the metal wiring. However, because aluminum is weak to stress and has a low hardness, an aluminum film may have various defects after the chemical mechanical polishing process in the damascene process. For example, the aluminum film may have defects such as dishing, erosion, corrosion, surface scratches and the like. The defects increase as the density of the aluminum pattern increases.

### SUMMARY OF THE INVENTION

The present invention provides a polishing slurry and a method of manufacturing a semiconductor device using the same.

According to an aspect of the present invention, a polishing slurry is provided for polishing an aluminum film; the polishing slurry includes an abrasive agent, an oxidizing agent, an anti-corrosion agent, and a removal rate reducing agent that is an anionic compound exhibiting a negative charge in the slurry.

According to another aspect of the present invention, a method of manufacturing a semiconductor device includes forming, on a substrate, an insulating film having trenches, forming an aluminum film on the insulating film to fill up the trenches, and polishing the aluminum film by using a first slurry for polishing aluminum to expose the insulating film, wherein the first slurry includes an abrasive agent, an oxidizing agent, an anti-corrosion agent, and a removal rate reducing agent that is an anionic compound exhibiting a negative charge in the first slurry.

The polishing slurry can prevent various defects occurring in an aluminum film after polishing in particular embodiments, though advantages of the present invention are not limited thereto, and other advantages will be described in or be apparent from the following description of embodiments. Moreover, other aspects of the present invention are included in the detailed description and drawings.

### BRIEF DESCRIPTION OF THE DRAWINGS

The above and other aspects and features of the present invention will become more apparent by describing in detail exemplary embodiments thereof with reference to the attached drawings, in which:

FIG. 1 illustrates scanning electron microscope (SEM) photographs showing surface states of an aluminum film after polishing according to types of anti-corrosion agents;

FIG. 2 is a graph showing a corrosion current value and a corrosion voltage value measured when using an anti-corrosion agent of piperazine;

FIG. 3 shows a polishing selectivity of an aluminum film to an insulating film according to addition of a removal rate reducing agent;

FIGS. 4 to 9 are cross-sectional views showing steps of a method of manufacturing a semiconductor device in accordance with embodiments of the present invention;

FIG. 10 shows dishing of the aluminum film due to a polishing slurry;

FIG. 11 shows erosion of the aluminum film due to the polishing slurry; and

FIG. 12 shows total defects of the aluminum film due to the polishing slurry.

### DETAILED DESCRIPTION

Advantages and features of the present invention and methods of accomplishing the same may be understood more readily by reference to the following detailed description of exemplary embodiments and the accompanying drawings. The present invention may, however, be embodied in many different forms and should not be construed as being limited to the embodiments set forth herein. Rather, these embodiments are provided so that this disclosure will be thorough and complete and will fully convey the concept of the invention to those skilled in the art, and the present invention will only be defined by the appended claims. In the drawings, sizes and relative sizes of layers and regions may be exaggerated for clarity.

It will be understood that when an element or layer is referred to as being “on” another element or layer, the element or layer can be directly on another element or layer or intervening elements or layers may also be present. In contrast, when an element is referred to as being “directly on” another element or layer, there are no intervening elements or layers present. As used herein, the term “and/or” includes any and all combinations of one or more of the associated listed items.

Spatially relative terms, such as “below”, “beneath”, “lower”, “above”, “upper”, and the like, may be used herein for ease of description to describe one element or feature's relationship to another element(s) or feature(s) as illustrated in the figures. It will be understood that the spatially relative terms are intended to encompass different orientations of the device in use or operation, in addition to the orientation depicted in the figures. Throughout the specification, like reference numerals in the drawings denote like elements.

Embodiments of the invention are described herein with reference to plan and cross-section illustrations that are schematic illustrations of idealized embodiments of the invention. As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. In the drawings, respective components may be enlarged or reduced in size for convenience of explanation.

First, a polishing slurry in accordance with an embodiment of the present invention will be described. The polishing slurry in this embodiment is a slurry for polishing an aluminum film, capable of minimizing corrosion, erosion, dishing, surface scratches and the like of an aluminum film after polishing, as described above. Particularly, the polishing slurry can have a low polishing selectivity of an aluminum film with respect to an insulating film such that the ratio of a removal rate of the aluminum film to a removal rate of the insulating film is equal to or smaller than a predetermined reference value, thereby minimizing dishing or erosion of the aluminum film that may occur when the aluminum film is more severely eroded than a neighboring insulating film. In order to obtain this effect, the polishing slurry mainly includes an abrasive agent, an oxidizing agent, an anti-corrosion agent, and a removal rate reducing agent. The respective agents will be described in detail, below.

First, the abrasive agent and the oxidizing agent will be described, below.

The abrasive agent is added to the slurry in accordance with an embodiment of the present invention to mechanically polish the aluminum film while ensuring a particular removal rate of the aluminum film. However, since the abrasive agent may increase generation of surface scratches, the type, particle size, content and the like of the abrasive agent may be appropriately adjusted.

The abrasive agent is an oxide-based abrasive agent, which is formed of, e.g., silica, colloidal silica, alumina, ceria, a combination thereof or the like. In particular embodiments, colloidal silica capable of minimizing surface scratches of the aluminum film after polishing may be used as the abrasive agent.

The abrasive agent may have an average particle size of 10 to 200 nm, in particular embodiments, 30 to 100 nm in order to reduce surface scratches in consideration of processing efficiency. Further, the abrasive agent may be present in an amount of 3 to 5 weight percent (wt %) with respect to the total weight of the slurry, which will be described later.

The oxidizing agent is added to the slurry in accordance with an embodiment of the present invention in order to ensure a particular removal rate of the aluminum film and prevent deterioration of the film quality from occurring in polishing. The oxidizing agent oxidizes the aluminum film that serves as a polishing target. The oxidizing agent may, however, increase surface roughness. Accordingly, in order to prevent an increase of surface roughness, the type, content and the like of the oxidizing agent may be appropriately adjusted. Further, the type, content and the like of the oxidizing agent may be appropriately adjusted so as to reduce the ratio of the removal rate of the aluminum film to the removal rate of the insulating film, i.e., to reduce a polishing selectivity of the aluminum film to the insulating film.

The oxidizing agent may be formed of hydrogen peroxide, ammonium cerium(IV) nitrate, ferric-propylenediaminetetraacetic acid (PDTA-Fe), ferric-ethylenediaminetetraacetic acid (EDTA-Fe), ferric nitrate or the like. In particular embodiments, the oxidizing agent is formed of ammonium cerium(IV) nitrate, ferric-propylenediaminetetraacetic acid (PDTA-Fe), ferric-ethylenediaminetetraacetic acid (EDTA-Fe) or a combination thereof so as to minimize the surface scratches of the aluminum film after polishing and exhibit a low polishing selectivity of the aluminum film to the insulating film. Further, in a specific embodiment, the oxidizing agent is formed of ferric-propylenediaminetetraacetic acid (PDTA-Fe) having a relatively low level of the surface scratches of the aluminum film after polishing and the lowest polishing selectivity of the aluminum film to the insulating film, which is supported by the experimental results shown in Table 1, below.

Table 1 shows the experimental results obtained by measuring removal rates of the aluminum film and the insulating film, a polishing selectivity of the aluminum film to the insulating film, and surface roughness of the aluminum film after polishing according to the types of oxidizing agents. Particularly, the experimental results were obtained by using a plasma enhanced tetraethoxysilane (PETEOS) film that is an oxide film as an insulating film. Specifically, Table 1 shows the experimental results obtained when the aluminum film and the PETEOS film were polished by using a slurry including an oxidizing agent that was foamed of any of the five compositions specified in the preceding paragraph and present in an amount of 1 wt %, and an abrasive agent that was formed of colloidal silica and present in an amount of 5 wt %.

TABLE 1

| | | Removal | | | |
|---|---|---|---|---|---|
| | | rates | | | |
| Experimental | | (Å/min) | | Al-to-Ox. | RMS |
| examples | Oxidizing agents | Al | PETEOS | Selectivity | (Å) |
| 1 | H₂O₂ | 1750 | 133 | 13.2 | 26.5 |
| 2 | ammonium | 1250 | 350 | 3.6 | 7.5 |
| | cerium (IV) nitrate | | | | |
| 3 | PDTA-Fe | 1120 | 375 | 3.0 | 6.8 |
| 4 | EDTA-Fe | 1300 | 370 | 3.5 | 6.6 |
| 5 | Ferric Nitrate | 1680 | 145 | 11.6 | 17.2 |

In Table 1, RMS (i.e., the root mean square average of the profile height deviations from the mean line) indicates analytical results of surface roughness of the aluminum film after polishing.

Referring to Table 1, it can be seen that when hydrogen peroxide or ferric nitrate was used as an oxidizing agent (i.e., Experimental example 1 or Experimental example 5), the polishing selectivity of the aluminum film to the insulating film was relatively high, and the surface roughness of the aluminum film after polishing was also relatively high. On the other hand, it can be seen that when ammonium cerium(IV) nitrate, ferric-propylenediaminetetraacetic acid (PDTA-Fe), or ferric-ethylenediaminetetraacetic acid (EDTA-Fe) was used as an oxidizing agent (i.e., Experimental example 2, Experimental example 3 or Experimental example 4), the polishing selectivity of the aluminum film to the insulating film was relatively low and surface roughness of the aluminum film after polishing was also relatively low. Further, it can be seen that when ferric-propylenediaminetetraacetic acid (PDTA-Fe) was used as an oxidizing agent (i.e., Experimental example 3), the polishing selectivity of the aluminum film to the insulating film had the lowest value, while surface roughness of the aluminum film after polishing was maintained at a low level.

Accordingly, as described above, ammonium cerium(IV) nitrate, ferric-propylenediaminetetraacetic acid (PDTA-Fe) or ferric-ethylenediaminetetraacetic acid (EDTA-Fe), particularly, ferric-propylenediaminetetraacetic acid, may be used as an oxidizing agent included in the slurry in accordance with an embodiment of the present invention.

Further, the oxidizing-agent content may be appropriately adjusted in order to ensure a low polishing selectivity of the aluminum film to the insulating film and a low surface roughness of the aluminum film after polishing. In particular embodiments, the oxidizing agent may be present in an amount of 0.1 to 0.7 weight percent (wt %) with respect to the total weight of the slurry, as supported by the experimental results shown in Table 2, below.

Table 2 shows experimental results obtained by measuring removal rates of the aluminum film and the insulating film, a polishing selectivity of the aluminum film to the insulating film, and surface roughness of the aluminum film after polishing according to the oxidizing-agent content and the abrasive-agent content. In particular, the experimental results were obtained by using a plasma enhanced tetraethoxysilane (PETEOS) film that is an oxide film as an insulating film. Specifically, Table 1 shows the experimental results obtained when the aluminum film and the PETEOS film were polished by using an oxidizing agent of ferric-propylenediaminetetraacetic acid (PDTA-Fe) and an abrasive agent of colloidal silica while varying the oxidizing-agent content and the abrasive-agent content.

TABLE 2

| | Oxidizing | Abrasive | | | | |
|---|---|---|---|---|---|---|
| Experi- | agent | agent | Removal rates | | | |
| mental | content | content | (Å/min) | | Al-to-Ox. | RMS |
| examples | (wt %) | (wt %) | Al | PETEOS | Selectivity | (Å) |
| 1 | 1 | 5 | 1120 | 375 | 3.0 | 6.6 |
| 2 | 0.7 | 5 | 900 | 370 | 2.4 | 6.2 |
| 3 | 0.5 | 5 | 780 | 372 | 2.1 | 6.2 |
| 4 | 0.2 | 5 | 720 | 350 | 2.1 | 5.7 |
| 5 | 0.1 | 5 | 700 | 345 | 2.0 | 5.1 |
| 6 | 0.2 | 7 | 750 | 430 | 1.7 | 6.4 |
| 7 | 0.2 | 3 | 715 | 320 | 2.2 | 5.1 |
| 8 | 0.2 | 1 | 710 | 120 | 5.9 | 4.6 |

As described above, the abrasive agent content of this embodiment may range from 3 to 5 wt %. Referring to Table 2, it can be seen that Experimental examples satisfying both a low polishing selectivity (e.g., about 2) of the aluminum film to the oxide film and low surface roughness (e.g., about 5 Å) of the aluminum film after polishing under the above conditions of the abrasive agent content are found in Experimental example 5, wherein the abrasive agent content was 5 wt % and the oxidizing agent content was 0.1 wt % and in Experimental example 7, wherein the abrasive agent content was 3 wt % and the oxidizing agent content was 0.2 wt %.

Meanwhile, in Experimental examples 2 to 4 (among the Experimental examples satisfying the conditions of the abrasive agent content of this embodiment) it can be seen that the surface roughness was only larger than that of Experimental example 5 or 7, while the polishing selectivity was maintained at a level similar to that of Experimental example 5 or 7.

Referring to Experimental examples 1 to 5 of Table 2, however, it can be seen that when the abrasive agent content was fixed at 5 wt %, the polishing selectivity and the surface roughness decreased as the oxidizing agent content was reduced. Further, referring to Experimental examples 6 to 8 of Table 2, it can be seen that when the oxidizing agent content was fixed at 0.2 wt %, as the abrasive agent content was reduced, the polishing selectivity increased, but the surface roughness decreased.

Based on the above, it can be predicted that the surface roughness will decrease if the abrasive agent content is further reduced to, e.g., about 3 wt % in Experimental examples 2 to 4. That is, in Experimental examples 2 to 4, if the oxidizing agent content is reduced while the abrasive agent content falls within a range in accordance with this embodiment, one can reduce the polishing selectivity and reduce the surface roughness.

Thus, as described above, the slurry of this embodiment may include an oxidizing agent ranging from about 0.1 to 0.7 wt %.

In brief, the slurry of this embodiment may include an abrasive agent ranging from 3 to 5 wt % and an oxidizing agent ranging from 0.1 to 0.7 wt %. In this case, colloidal silica may be used as the abrasive agent. Further, ammonium cerium(IV) nitrate, ferric-propylenediaminetetraacetic acid (PDTA-Fe), or ferric-ethylenediaminetetraacetic acid (EDTA-Fe) may be used as the oxidizing agent.

Next, the anti-corrosion agent is described below.

The anti-corrosion agent is added to the slurry of this embodiment in order to prevent the surface of the aluminum film from being partially corroded in a polishing process.

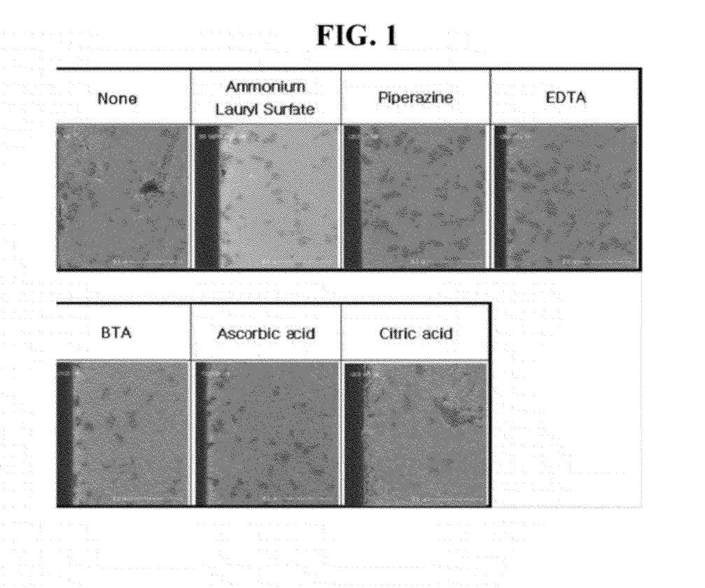

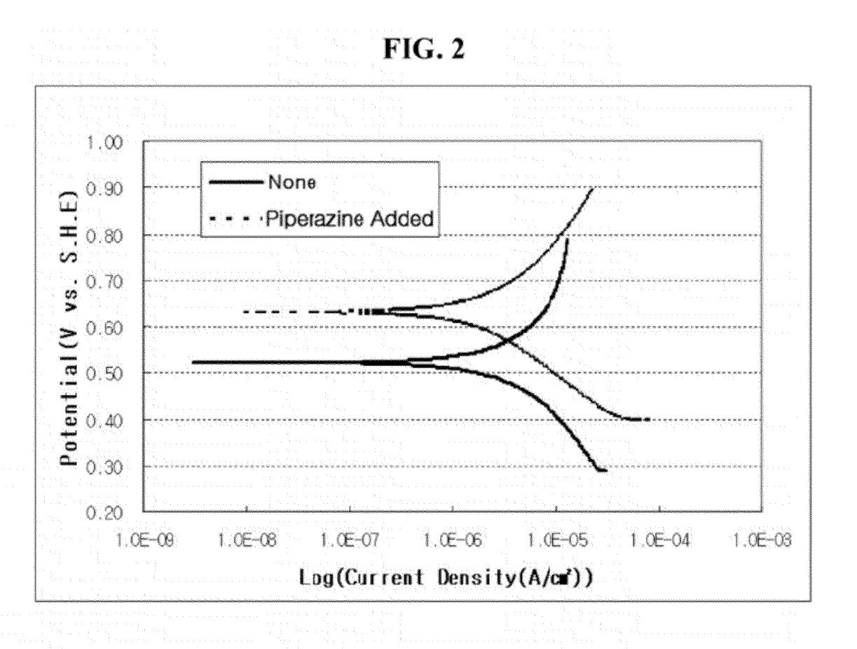

The anti-corrosion agent may be formed of ammonium lauryl sulfate (ALS), piperazine, ethylene diamine tetra acetic acid (EDTA), benzotrialole (BTA), ascorbic acid, citric acid or the like. In this case, the anti-corrosion agent can be formed of piperazine capable of minimizing the occurrence of corrosion and, particularly, preventing the interfacial corrosion, which is supported by the experimental results shown in FIGS. 1 and 2.

FIG. 1 illustrates scanning-electron-microscope (SEM) photographs showing surface states of the aluminum film after polishing according to types of anti-corrosion agents. In particular, FIG. 1 shows the experimental results obtained when the aluminum film was polished by using the slurry including the abrasive agent of colloidal silica present in an amount of 3 wt % and the oxidizing agent of ferric-propylenediaminetetraacetic acid (PDTA-Fe) present in an amount of 0.2 wt %, to which each of the above-mentioned types of anti-corrosion agents was added at an amount of 500 ppm.

Referring to FIG. 1, the occurrence of corrosion at the surface of the aluminum film is shown to be reduced in a case in which the anti-corrosion agent was added to the slurry as compared to a case in which the anti-corrosion agent was not added to the slurry. Particularly, it can be seen that the interfacial corrosion was suppressed when piperazine was added as the anti-corrosion agent.

FIG. 2 is a graph showing a corrosion current value and a corrosion voltage value measured when using the anti-corrosion agent of piperazine. Particularly, FIG. 2 illustrates the experimental results obtained by analyzing an oxidation reduction potential of the aluminum film after the aluminum film was polished by using the slurry including an abrasive agent of colloidal silica, which was present in an amount of 3 wt %; an oxidizing agent of ferric-propylenediaminetetraacetic acid (PDTA-Fe), which was present in an amount of 0.2 wt %; and an anti-corrosion agent of piperazine, which was present in an amount of 500 ppm.

Referring to FIG. 2, the corrosion current value decreased, and the corrosion voltage value increased to thereby suppress the corrosion of the aluminum film in a case in which the anti-corrosion agent of piperazine was added to the slurry as compared to a case in which the anti-corrosion agent of piperazine was not added to the slurry.

Meanwhile, piperazine has a chemical structure in the form of Chemical formula 1, below.

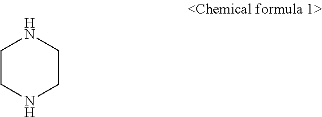

The piperazine, having the above structure, is a compound including at least one nitrogen atom in an aromatic ring, wherein the nitrogen atom may be coupled directly to a hydrogen atom capable of being dissociated into a hydrogen ion in the slurry. Accordingly, the piperazine is dissolved in the slurry to release a hydrogen atom and, then, is coupled with the aluminum film to be polished, thereby passivating the surface of the aluminum film to suppress the corrosion of the aluminum film. Thus, various compounds having a structure similar to that of the piperazine, that is, a structure including at least one nitrogen atom in an aromatic ring, wherein the nitrogen atom is coupled directly to a hydrogen atom, may be used as the anti-corrosion agent by the above-described mechanism.

Further, various compounds having a structure including at least one nitrogen atom in an aromatic ring similar to the structure of the piperazine, the nitrogen atom being not coupled directly to a hydrogen atom, may alternatively/also be used as the anti-corrosion agent because compounds having a structure including at least one nitrogen atom in an aromatic ring can be coupled with the aluminum film to be polished by the lone pair of electrons present in a nitric group, thereby passivating the surface of the aluminum film.

Similarly to the piperazine, other compounds that may be used as the anti-corrosion agent include a compound including at least one nitrogen atom in an aromatic ring or a compound having a structure including at least one nitrogen atom in an aromatic ring, the nitrogen atom being coupled directly to a hydrogen atom, for example, pyridine, 1-(2-pyrimidinyl)-piperazine, piperidine, benzylpiperazine (BZP), 3-chlorophenylpiperazine, 3-trifluoromethylphenylpiperazine monohydrochloride (TFMPP.HCl), piperine or a combination thereof.

The anti-corrosion agent may be added at an amount of 50 to 1000 ppm of the slurry. That is, although the piperazine at 500 ppm is added to the slurry of this embodiment in Experimental examples of FIGS. 1 and 2, the present invention is not limited thereto. Piperazine in an amount ranging from 50 to 1000 ppm may be added to the slurry in accordance with an embodiment of the present invention.

In brief, the slurry of this embodiment may include the anti-corrosion agent ranging from 50 to 1000 ppm of the slurry, in addition to the abrasive agent and the oxidizing agent, as described above. In this case, piperazine, pyridine, 1-(2-pyrimidinyl)-piperazine, piperidine, benzylpiperazine (BZP), 3-chlorophenylpiperazine, 3-trifluoromethylphenylpiperazine monohydrochloride (TFMPP.HCl) or piperine may be used as the anti-corrosion agent.

Next, the removal rate reducing agent will be described, below.

The removal rate reducing agent is used to selectively reduce only the removal rate of the aluminum film in the polishing of the aluminum film and/or the insulating film. The removal rate reducing agent is added to the slurry of this embodiment in order to further reduce a polishing selectivity of the aluminum film to the insulating film

As described above, the polishing slurry in accordance with an embodiment of the present invention is designed to reduce or minimize dishing or erosion of the aluminum film, which can occur when the aluminum film is more severely eroded than the neighboring insulating film. To reduce excessive dishing or erosion of the aluminum film, the polishing slurry in accordance with an embodiment of the present invention is designed to reduce a polishing selectivity of the aluminum film to the insulating film. Referring to Table 2 and the description thereof, as explained above, however, one can see that the polishing selectivity of the aluminum film to the oxide film was maintained at a level of about 2 even though the type and content of the abrasive agent and the type and content of the oxidizing agent were varied. In this embodiment, the removal rate reducing agent is used to further reduce a polishing selectivity of the aluminum film to the oxide film, for example, to be equal to or smaller than 1.

The removal rate reducing agent employs an anionic compound exhibiting a negative charge in the polishing slurry in accordance with an embodiment of the present invention. In this case, the “anionic compound” has a wide scope, including not only an anionic high molecular compound but also an anionic monomer. The anionic compound serving as the removal rate reducing agent may be formed of any composition selected from polyacrylic acid (PAA), polymethacrylic acid, ammonium polymethacrylate, polycarboxylate, sodium dodecyl sulfate, alkylbenzene sulfonate, α-olefin sulfonate, mono alkyl phosphate, sodium salt of fatty acid, carboxyl acrylic polymer and a combination thereof.

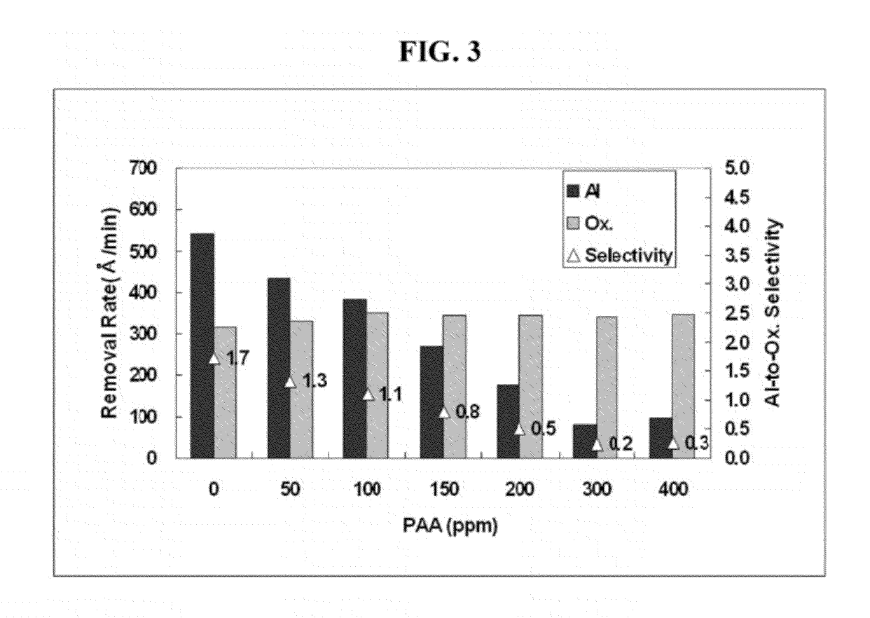

When the aluminum film to be polished is in contact with the slurry, the aluminum film exhibits a relatively positive charge in the slurry. Accordingly, when the aluminum film is polished by using the slurry, including the removal rate reducing agent, as described above, an anionic substance generated from the anionic compound and a cationic substance generated from the aluminum film couple with each other and are adsorbed to the surface of the aluminum film. Accordingly, when the aluminum film and the insulating film are polished using the slurry, including the removal rate reducing agent, only the removal rate of the aluminum film is selectively reduced, thereby reducing a polishing selectivity of the aluminum film to the insulating film to be equal to or smaller than 1, which is supported by the experimental results as shown in FIG. 3.

FIG. 3 shows a polishing selectivity of the aluminum film to the insulating film due to the addition of the removal rate reducing agent. Particularly, FIG. 3 illustrates experimental results obtained by measuring the removal rate of the aluminum film, the removal rate of the oxide film and the polishing selectivity of the aluminum film to the oxide film when the polyacrylic acid (PAA), ranging from 0 to 400 ppm, was added as the removal rate reducing agent to the slurry, including the abrasive agent of colloidal silica, which was present in an amount of 3 wt % of the slurry; the oxidizing agent of ferric-propylenediaminetetraacetic acid (PDTA-Fe), which was present in an amount of 0.2 wt % of the slurry; and the anti-corrosion agent of piperazine, which was present in an amount of 500 ppm of the slurry.

Referring to FIG. 3, the removal rate of the aluminum film can be seen to decrease as the removal rate reducing agent (polyacrylic acid (PAA)) content of the slurry increases. Further, in this case, the removal rate of the oxide film is can be seen to be maintained substantially constant. As a result, a polishing selectivity of the aluminum film to the oxide film decreases to be equal to or smaller than 1 as the removal rate reducing agent (polyacrylic acid (PAA)) content of the slurry increases. The removal rate reducing agent may be added at an amount of 50 to 1000 ppm of the slurry.

In brief, the slurry of this embodiment may include the removal rate reducing agent in a concentration at 50 to 1000 ppm of the slurry in addition to the abrasive agent, the oxidizing agent and the anti-corrosion agent, as described above. In this case, the removal rate reducing agent is formed of an anionic compound, i.e., any composition selected from polyacrylic acid (PAA), polymethacrylic acid, ammonium polymethacrylate, polycarboxylate, sodium dodecyl sulfate, alkylbenzene sulfonate, α-olefin sulfonate, mono alkyl phosphate, sodium salt of fatty acid, carboxyl acrylic polymer and a combination thereof.

In addition, the slurry of this embodiment may further include a pH adjuster.

The pH adjuster serves to adjust the pH of the slurry within an appropriate range. In particular embodiments, the polishing slurry of this embodiment has a pH in the range of acid. To adjust the pH into this range, the pH adjuster may employ an inorganic acid such as nitric acid, sulfuric acid and hydrochloric acid, or an organic acid such as acetic acid.

When the aluminum film is polished using the slurry, as described above, not only may corrosion of the aluminum film be prevented and surface scratches be minimized, but also polishing selectivity of the aluminum film to the insulating film may be reduced. Accordingly, dishing or erosion of the aluminum film may be prevented, which may otherwise occur in a damascene process, described infra.

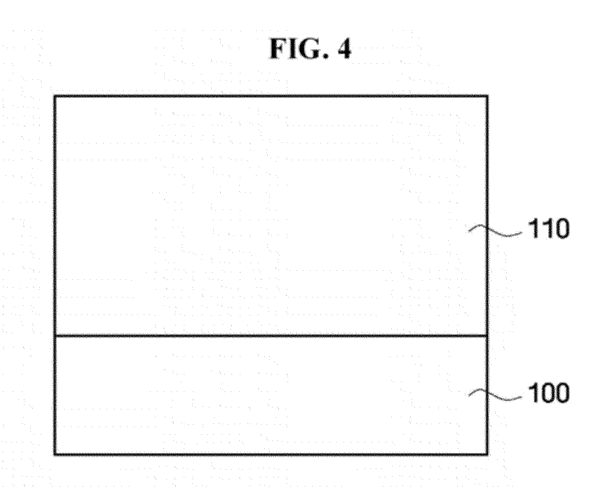

Hereinafter, a method of manufacturing a semiconductor device in accordance with embodiments of the present invention will be described with reference to FIGS. 4 to 9. A method of manufacturing a semiconductor device in accordance with embodiments of the present invention includes a step of performing a damascene process using the above-described polishing slurry.

FIGS. 4 to 7 are cross sectional views showing the steps of a method of manufacturing a semiconductor device in accordance with a first embodiment of the present invention.

Referring to FIG. 4, a substrate structure 100 including a specific desired structure (not shown) is provided. For example, the substrate structure 100 may be a multilayer structure including transistors, metal wirings and the like. However, the present invention is not limited thereto; and the substrate structure 100 may have various structures according to the requirements of the semiconductor devices.

Subsequently, an insulating film 110 is formed on the substrate structure 100. The insulating film 110 may be fanned of an oxide film, e.g., a high density plasma (HDP) film, a plasma-enhanced tetra ethyl ortho silicate (PETEOS) film, a phosphorus silicate glass (PSG) film, an undoped silicate glass (USG) film, a spin on glass (SOG) film, a silicon rich oxide (SROX) film, an atomic layer deposition (ALD) film and the like. However, the present invention is not limited thereto, and the insulating film may be formed of a low dielectric constant (low-k) material or the like.

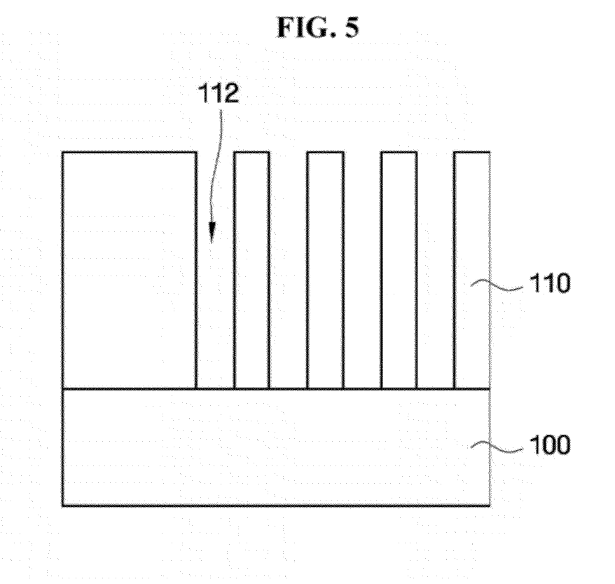

Subsequently, referring to FIG. 5, after a specific mask pattern (not shown) made of, e.g., a photoresist is formed on the insulating film 110, the insulating film 110 is etched to a predetermined depth using the mask pattern as an etching mask, thereby forming trenches 112 in the insulating film 110.

In this case, the trenches 112 are formed in a desired shape of an aluminum film pattern to provide a space for forming the aluminum film pattern. Further, the trench 112 may be formed to expose a desired portion of the substrate structure 100. For example, the trenches 112 may be formed in a linear shape for forming a line or a hole shape for forming a contact, via or the like to expose a portion of the substrate structure 100. However, the present invention is not limited thereto, and the trenches 112 may be formed in various shapes according to requirements of semiconductor devices. The portion of the substrate structure 100 exposed by the trenches 112 may be variously modified.

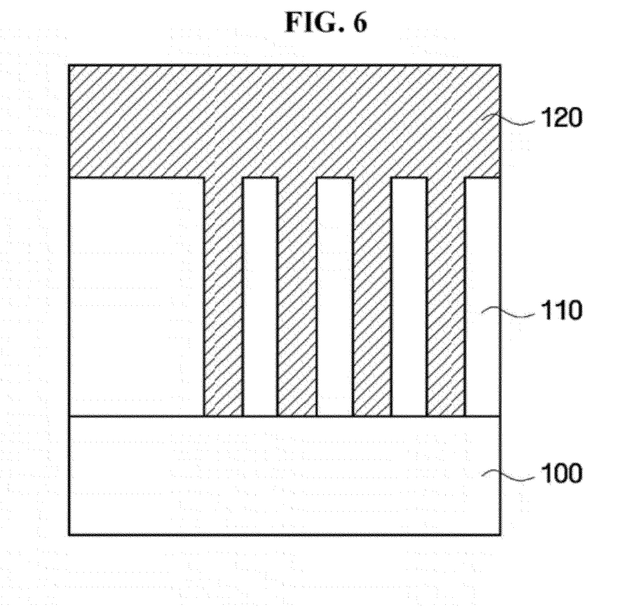

Subsequently, referring to FIG. 6, an aluminum film 120 is formed on the insulating film 110 having trenches 112 with a thickness capable of sufficiently covering an upper surface of the insulating film 110 while filling up the trenches 112. The aluminum film 120 may be formed by any of various deposition processes.

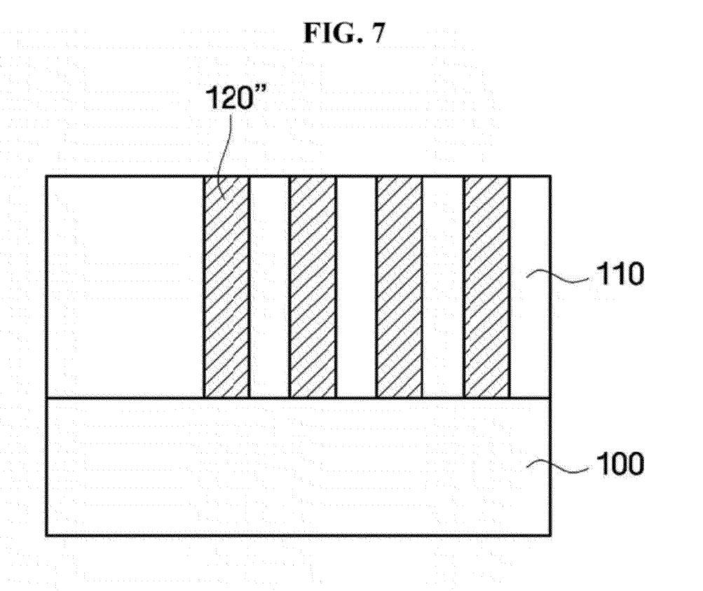

Subsequently, referring to FIG. 7, the aluminum film 120 is polished to completely expose the insulating film 110. Accordingly, an aluminum film pattern 120″ is formed with portions embedded in the trenches 112 and separated from each other. As described above, in a case where the trenches 112 have a linear shape, the aluminum film pattern 120″ may be used as linear aluminum wires. Alternatively, in a case where the trenches 112 have a hole shape, the aluminum film pattern 120″ may be used as cylindrical aluminum vias or contacts. However, the present invention is not limited thereto, and the aluminum film pattern 120″ may be used as various conductive patterns included in semiconductor devices.

In this case, polishing of the aluminum film 120 is performed using the above-described polishing slurry. In other words, polishing of the aluminum film 120 may be performed using a slurry including the abrasive agent, the oxidizing agent, the anti-corrosion agent and the removal rate reducing agent that is an anionic compound exhibiting a negative charge in the slurry. Since the slurry is described in detail, above, a repeated description thereof will be omitted here.

As described above, when the aluminum film 120 is polished using the polishing slurry in accordance with an embodiment of the present invention, it is possible to prevent corrosion of the aluminum film 120 and minimize surface scratches. Further, since a polishing selectivity of the aluminum film 120 to the insulating film 110 is equal to or smaller than 1 in the polishing slurry in accordance with an embodiment of the present invention, the aluminum film 120 and the insulating film 110 may have the same thickness or the insulating film 110 may be more polished than the aluminum film 120 in a polishing process of the aluminum film 120. The surface of the aluminum film pattern 120″ formed after polishing may therefore be flush with the surface of the insulating film 110 or may slightly protrude from the surface of the insulating film 110, thereby preventing dishing or erosion of the aluminum film pattern 120″.

FIGS. 4 to 6 and 8 to 9 are cross sectional views showing the steps of a method of manufacturing a semiconductor device in accordance with a second embodiment of the present invention. The method of the second embodiment is different from the method of the first embodiment in that the polishing of the aluminum film 120 includes two steps (i.e., first and second steps). In this embodiment, polishing of the aluminum film 120 is performed in two steps in order to increase the total processing speed by increasing the removal rate of the aluminum film 120 while ensuring the above-described effects.

First, the same steps as those of FIGS. 4 to 6 are performed. Since these steps are described in detail above, a repeated description thereof is omitted. Consequently, the structure shown in FIG. 6 is provided.

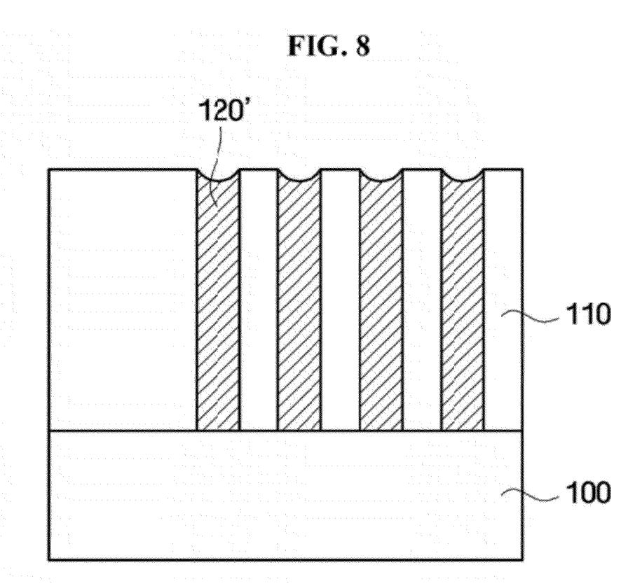

Subsequently, referring to FIG. 8, the aluminum film 120 is polished primarily to expose the insulating film 110, thereby forming a preliminary aluminum film pattern 120′.

In this case, the primary polishing of the aluminum film 120 is performed using a polishing slurry having a high polishing selectivity of the aluminum film 120 to the insulating film 110 instead of the previously described polishing slurry. For example, the primary polishing may be performed using a slurry in which the polishing selectivity of the aluminum film 120 to the insulating film 110 is equal to or larger than 50:1. An example of a polishing slurry having high polishing selectivity for the aluminum film 120 over the insulating film 110 is a mixture that includes alumina abrasive (with a particle size of 95 nm) and hydrogen peroxide, which is available as A7100 polishing slurry from Cabot Microelectronics Corporation (Aurora, Ill.). In this case, the removal rate of the aluminum film 120 increases in the primary polishing step, thereby increasing the total processing speed.

However, in the case of using the slurry having a high polishing selectivity of the aluminum film 120 to the insulating film 110, dishing or erosion of the aluminum film pattern 120′ after the primary polishing may occur. Accordingly, using the insulating film 110 as a polishing stop film, the primary polishing is stopped when the insulating film 110 is exposed. Consequently, the preliminary aluminum film pattern 120′, after the primary polishing, has a recessed shape slightly depressed from the surface of the insulating film 110.

When the primary polishing step is performed as described above, the preliminary aluminum film pattern 120′, after the primary polishing, may remain on the insulating film 110 and may have portions embedded in the trenches 112 which are not completely separated from each other. Accordingly, secondary polishing is performed as will be described, below, in order to prevent this phenomenon.

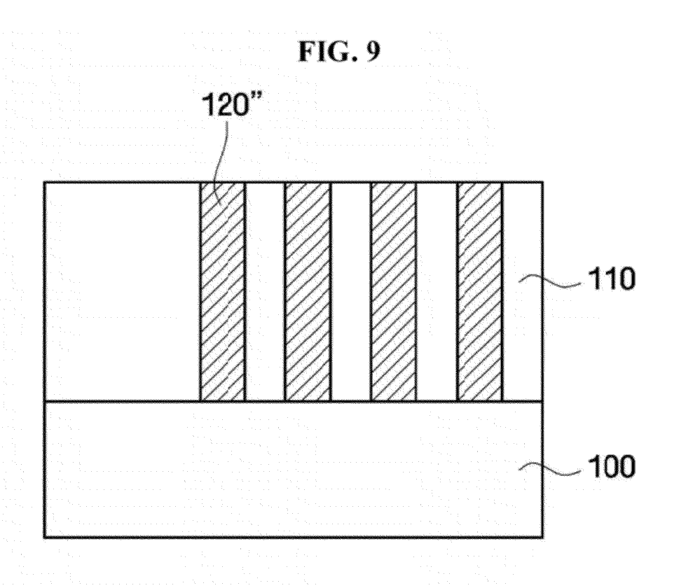

Referring to FIG. 9, the insulating film 110 and the aluminum film 120 are polished by a secondary polishing step to a predetermined thickness to completely expose the insulating film 110. Accordingly, the aluminum film pattern 120″ is formed with portions embedded in the trenches 112 that are separated from each other.

In this case, the secondary polishing of the aluminum film 120 is performed by using the above-described polishing slurry. In other words, the secondary polishing step of the aluminum film 120 may be performed by using the slurry including the abrasive agent, the oxidizing agent, the anti-corrosion agent and the removal rate reducing agent that is an anionic compound exhibiting a negative charge in the slurry. Since this slurry is described in detail above, a repeated description thereof will be omitted here.

As described above, when the secondary polishing of the aluminum film 120 is performed using the polishing slurry in accordance with an embodiment of the present invention, it is possible to prevent corrosion of the aluminum film 120 and minimize the surface scratches. Further, since a polishing selectivity of the aluminum film 120 to the insulating film 110 is equal to or smaller than 1 in a polishing slurry in accordance with an embodiment of the present invention, the aluminum film 120 and the insulating film 110 may have the same thickness, or the insulating film 110 may be more polished than the aluminum film 120 in a polishing process of the aluminum film 120. The surface of the aluminum film pattern 120″ formed after polishing may therefore be flush with the surface of the insulating film 110 or may slightly protrude from the surface of the insulating film 110, thereby preventing dishing or erosion of the aluminum film pattern 120″.

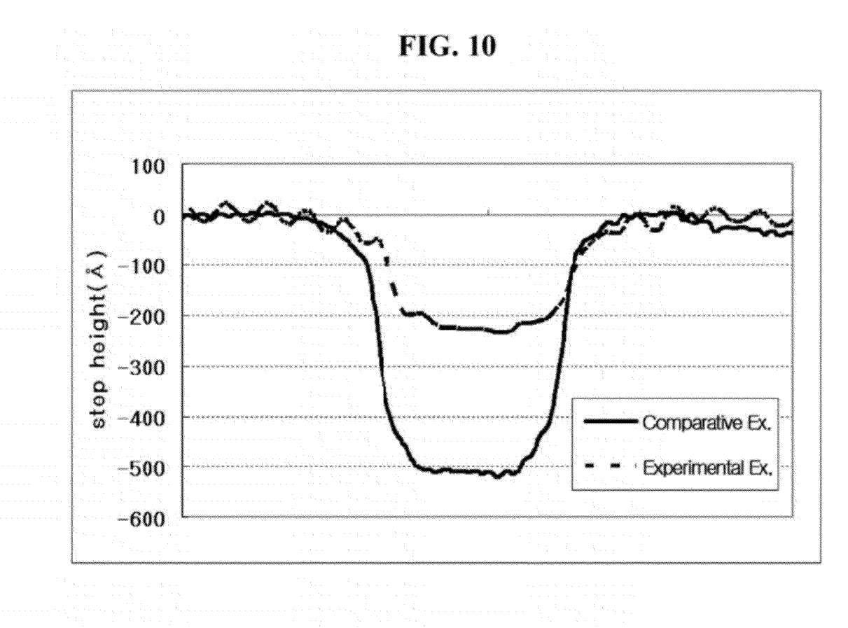

The effects of the method of manufacturing a semiconductor device, as described above, are evidenced by FIGS. 10 to 12.

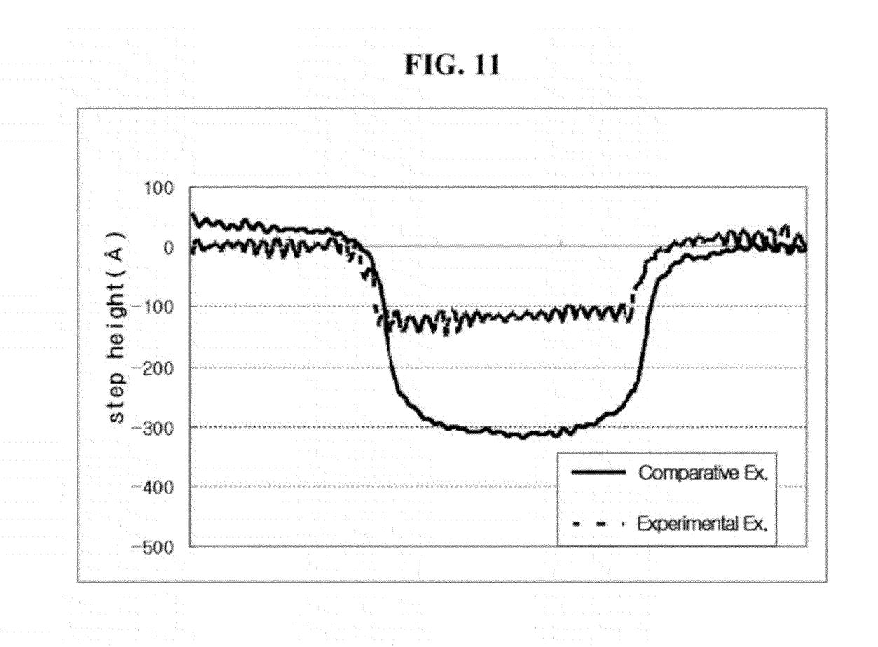

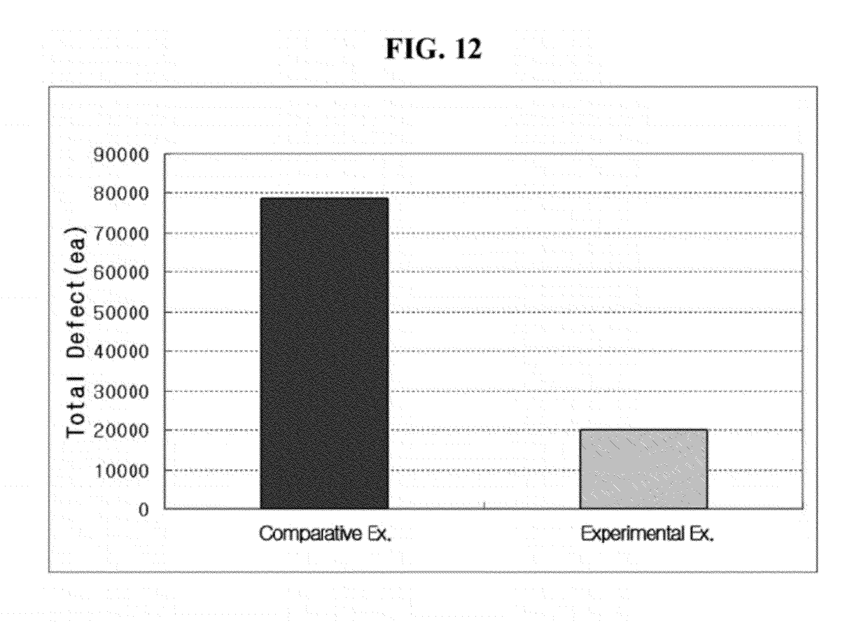

FIG. 10 shows dishing of the aluminum film due to the polishing slurry. FIG. 11 shows erosion of the aluminum film due to the polishing slurry. FIG. 12 shows total defects of the aluminum film due to the polishing slurry. The Experimental examples of FIGS. 10, 11 and 12 show the experimental results obtained by performing a polishing process including two steps in the method of manufacturing a semiconductor device in accordance with the second embodiment of the present invention, wherein a secondary polishing step was performed by using the polishing slurry in accordance with an embodiment of the present invention, which includes the abrasive agent of colloidal silica present in an amount of 3 wt %, the oxidizing agent of ferric-propylenediaminetetraacetic acid (PDTA-Fe) present in an amount of 0.2 wt %, the anti-corrosion agent of piperazine present in an amount of 500 ppm, and the removal rate reducing agent of polyacrylic acid (PAA). On the other hand, the comparative examples of FIGS. 10, 11 and 12 show the experimental results obtained by performing a polishing process on the aluminum film using only the slurry having a high polishing selectivity of the aluminum film 120 to the insulating film 110, for comparison with the experimental examples.

Referring to FIGS. 10 and 11, one can see that the surface height difference was reduced in the experimental examples compared to the comparative examples, which means that dishing and erosion of the aluminum film were reduced in the experimental examples.

Further, referring to FIG. 12, one can see that total defects in the aluminum film, such as aluminum corrosion and surface scratches, are reduced in the experimental examples compared to the comparative examples.

In brief, in the polishing of an aluminum film, primary polishing is performed by using a slurry having a high polishing selectivity until an insulating film is exposed, and then secondary polishing is performed on the aluminum film and the insulating film to reach a predetermined thickness using a slurry having a low polishing selectivity in accordance with an embodiment of the present invention. Accordingly, it is possible to minimize defects occurring when the aluminum film is polished, i.e., dishing, erosion, corrosion, surface scratches and the like of the aluminum film.

While the present invention has been particularly shown and described with reference to exemplary embodiments thereof, those of ordinary skill in the art will understand that various changes in form and detail may be made therein without departing from the spirit and scope of the present invention as defined by the following claims. The exemplary embodiments should be considered in a descriptive sense only and not for purposes of limitation.

What is claimed is:

1. A polishing slurry for polishing an aluminum film comprising:
an abrasive agent;
an oxidizing agent;
an anti-corrosion agent; and
a removal rate reducing agent that is an anionic compound exhibiting a negative charge in the slurry.

2. The polishing slurry of claim 1, wherein the removal rate reducing agent is selected from polyacrylic acid (PAA), polymethacrylic acid, ammonium polymethacrylate, polycarboxylate, sodium dodecyl sulfate, alkylbenzene sulfonate, α-olefin sulfonate, mono alkyl phosphate, sodium salt of fatty acid, carboxyl acrylic polymer and a combination thereof.

3. The polishing slurry of claim 2, wherein the removal rate reducing agent content of the slurry is in a range from 50 to 1000 ppm.

4. The polishing slurry of claim 1, wherein the anti-corrosion agent is a compound including at least one nitrogen atom in an aromatic ring.

5. The polishing slurry of claim 4, wherein the anti-corrosion agent is selected from pyridine, 1-(2-pyrimidinyl)-piperazine, piperidine, benzylpiperazine (BZP), 3-chlorophenylpiperazine, 3-trifluoromethylphenylpiperazine monohydrochloride (TFMPP.HCl), piperine and a combination thereof.

6. The polishing slurry of claim 5, wherein the anti-corrosion agent content of the slurry is in a range from 50 to 1000 ppm.

7. The polishing slurry of claim 1, wherein the oxidizing agent is selected from ammonium cerium(IV) nitrate, ferric-propylenediaminetetraacetic acid (PDTA-Fe), ferric-ethylenediaminetetraacetic acid (EDTA-Fe) and a combination thereof.

8. The polishing slurry of claim 7, wherein the oxidizing agent content of the slurry is in a range from 0.1 to 0.7 wt %.

9. The polishing slurry of claim 8, wherein the abrasive agent content of the slurry is in a range from 3 to 5 wt %.

10. The polishing slurry of claim 1, further comprising a pH adjuster to adjust the pH of the slurry such that the slurry has an acidic pH.

11. The polishing slurry of claim 1, wherein in a polishing process using the slurry, a polishing selectivity of the aluminum film to an insulating film is equal to or smaller than 1.

12. A method of manufacturing a semiconductor device comprising:
forming an insulating film having trenches on a substrate;
forming an aluminum film on the insulating film to fill the trenches; and
polishing the aluminum film using a first slurry for polishing aluminum to expose the insulating film,
wherein the first slurry includes an abrasive agent, an oxidizing agent, an anti-corrosion agent, and a removal rate reducing agent that is an anionic compound exhibiting a negative charge in the first slurry.

13. The method of claim 12, wherein said polishing the aluminum film comprises:
primarily polishing the aluminum film using a second slurry for polishing aluminum while the insulating film is used as a polishing stop film; and
secondarily polishing the insulating film and the aluminum film using the first slurry,
wherein the second slurry has a higher polishing selectivity of the aluminum film to the insulating film as compared to the first slurry.

14. The method of claim 13, wherein the first slurry has a polishing selectivity of the aluminum film to the insulating film equal to or smaller than 1.

15. The method of claim 13, wherein the removal rate reducing agent is selected from polyacrylic acid (PAA), polymethacrylic acid, ammonium polymethacrylate, polycarboxylate, sodium dodecyl sulfate, alkylbenzene sulfonate, α-olefin sulfonate, mono alkyl phosphate, sodium salt of fatty acid, carboxyl acrylic polymer and a combination thereof.

16. The method of claim 15, wherein the removal rate reducing agent content of the first slurry is in a range from 50 to 1000 ppm.

17. The method of claim 13, wherein the anti-corrosion agent is a compound including at least one nitrogen atom in an aromatic ring.

18. The method of claim 17, wherein the anti-corrosion agent is selected from pyridine, 1-(2-pyrimidinyl)-piperazine, piperidine, benzylpiperazine (BZP), 3-chlorophenylpiperazine, 3-trifluoromethylphenylpiperazine monohydrochloride (TFMPP.HCl), piperine and a combination thereof.

19. The method of claim 18, wherein the anti-corrosion agent content of the first slurry is in a range from 50 to 1000 ppm.

20. The method of claim 13, wherein the oxidizing agent is selected from ammonium cerium(IV) nitrate, ferric-propylenediaminetetraacetic acid (PDTA-Fe), ferric-ethylenediaminetetraacetic acid (EDTA-Fe) and a combination thereof.

21. The method of claim 20, wherein the oxidizing agent content of the first slurry is in a range from 0.1 to 0.7 wt %.

22. The method of claim 21, wherein the abrasive agent content of the first slurry is in a range from 3 to 5 wt %.

23. The method of claim 13, wherein the first slurry further includes a pH adjuster to adjust pH of the first slurry such that the first slurry has an acidic pH.

24. The method of claim 12, wherein the insulating film includes an oxide film.

25. A polishing slurry for polishing an aluminum film comprising:
an oxide-based abrasive agent;
an oxidizing agent selected from ammonium cerium(IV) nitrate, ferric-propylenediaminetetraacetic acid (PDTA-Fe), ferric-ethylenediaminetetraacetic acid (EDTA-Fe) and a combination thereof;
an anti-corrosion agent including at least one nitrogen atom in an aromatic ring; and
a removal rate reducing agent selected from polyacrylic acid (PAA), polymethacrylic acid, ammonium polymethacrylate, polycarboxylate, sodium dodecyl sulfate, alkylbenzene sulfonate, α-olefin sulfonate, mono alkyl phosphate, sodium salt of fatty acid, carboxyl acrylic polymer and a combination thereof.

26. The polishing slurry of claim 25, wherein the anti-corrosion agent is selected from pyridine, 1-(2-pyrimidinyl)-piperazine, piperidine, benzylpiperazine (BZP), 3-chlorophenylpiperazine, 3-trifluoromethylphenylpiperazine monohydrochloride (TFMPP.HCl), piperine and a combination thereof.

27. The polishing slurry of claim 25, wherein:
the abrasive agent content of the slurry is in a range from 3 to 5 wt %;
the oxidizing agent content of the slurry is in a range from 0.1 to 0.7 wt %;
the anti-corrosion agent content of the slurry is in a range from 50 to 1000 ppm; and
the removal rate reducing agent content of the slurry is in a range from 50 to 1000 ppm.
